(19) United States
(12) Patent Application Publication
(10) Pub. No.: US 2022/0076991 A1
(43) Pub. Date: Mar. 10, 2022

(54) SUBSTRATE OF THE SEMI-CONDUCTOR-ON-INSULATOR TYPE FOR RADIOFREQUENCY APPLICATIONS

(71) Applicant: Soitec, Bernin (FR)

(72) Inventors: Kim Young Pil, Grenoble (FR); Christelle Veytizou, Bernin (FR)

(21) Appl. No.: 17/416,948

(22) PCT Filed: Dec. 19, 2019
(86) PCT No.: PCT/FR2019/053192

§ 371 Date: Jun. 21, 2021

(30) Foreign Application Priority Data
Dec. 21, 2018 (FR) 1873888

(51) Int. Cl. H01L 21/762; H01L 21/322; H01L 21/02; H01L 27/12

(52) U.S. Cl. CPC H01L 21/76254; H01L 27/1207; H01L 21/02002; H01L 21/3226

(57) ABSTRACT

A semiconductor-on-insulator substrate for radio-frequency applications, comprises: —a silicon carrier substrate, —an electrically insulating layer arranged on the carrier substrate, —a single-crystal layer arranged on the electrically insulating layer, the substrate being characterized in that it further comprises a layer of silicon carbide SiC arranged between the carrier substrate and the electrically insulating layer, which has a thickness between 1 nm and 5 nm, the surface of the layer of silicon carbide SiC that is on the side of the electrically insulating layer being rough.

### CROSS-REFERENCE TO RELATED APPLICATIONS

This application is a national phase entry under 35 U.S.C. § 371 of International Patent Application PCT/FR2019/053192, filed Dec. 19, 2019, designating the United States of America and published as International Patent Publication WO 2020/128354 A1 on Jun. 25, 2020, which claims the benefit under Article 8 of the Patent Cooperation Treaty to French Patent Application Serial No. 1873888, filed Dec. 21, 2018.

### TECHNICAL FIELD

The present disclosure relates to a semiconductor-on-insulator substrate for radio-frequency applications. The present disclosure also relates to a process for fabricating such a substrate by transferring a layer from a donor substrate to a receiver substrate.

### BACKGROUND

Semiconductor-on-insulator substrates are multilayer structures comprising a carrier substrate, which is generally made of silicon, an electrically insulating layer that is arranged on the substrate and typically a silicon-oxide layer, and a semiconductor layer, called the active layer and in which electronic components are produced, that is arranged on the insulating layer and that is generally a silicon layer.

Such substrates are referred to as SeOI substrates (SeOI being the acronym of semiconductor-on-insulator), or in particular SOI substrates when the semiconductor material is silicon (SOI being the acronym of silicon-on-insulator).

The oxide layer, which is located between the carrier substrate and the active layer, is then said to be “buried,” and is called the “BOX” (BOX being the acronym of buried oxide).

SOI substrates are widely used to fabricate radio-frequency devices. In this case, radio-frequency components are produced in the active layer.

A recurrent problem with SOI substrates for radio-frequency applications is that electric charge trapped in the BOX layer leads to an accumulation under the same layer, in the carrier substrate, of charge of opposite sign, forming an electrically conductive plane.

In this conductive plane, mobile charge carriers are likely to interact strongly with the electromagnetic fields generated by the radio-frequency components of the active layer. A large drop in the resistivity of the carrier substrate, in a plane located directly under the BOX layer, is then observed, even when the carrier substrate has a high electrical resistivity.

This leads to some of the energy of the signal being needlessly consumed because of coupling loss between the radio-frequency components and the substrate, and of possible crosstalk between the radio-frequency components themselves.

In addition, the charge carriers of the substrate may generate unwanted harmonics that are liable to interfere with the signals propagating through the radio-frequency device and to degrade their quality.

To limit these effects, it is known practice to insert a polysilicon charge-trapping layer between the BOX layer and the carrier substrate, directly under the BOX layer. The boundaries of the grains forming the crystal then form traps for the charge carriers, the trapped charge carriers possibly originating from the trapping layer itself or from the subjacent carrier substrate. In this way, the appearance of the conductive plane under the electrically insulating layer and the drop in the resistivity of the carrier substrate are prevented.

However, the effectiveness of such a charge-trapping layer is not always optimal, and the effects of coupling loss and of generation of unwanted harmonics may nevertheless occur.

In particular, the polysilicon layer, which makes contact with the carrier substrate, which is made of single-crystal silicon, has a tendency to recrystallize under the effect of heat treatments applied to the substrate during its fabrication and the fabrication of the radio-frequency components. Specifically, the carrier substrate serves as a seed for the recrystallization. The recrystallization of the polysilicon layer, as it reduces the number of grains, also reduces the capacity of the layer to trap electric charge.

### BRIEF SUMMARY

One goal of the present disclosure is to provide a semiconductor-on-insulator substrate that allows the aforementioned drawbacks to be overcome.

The present disclosure aims to provide such a substrate allowing interactions between mobile charge carriers in the substrate and the electromagnetic fields generated by the radio-frequency components of the active layer to be limited.

The present disclosure therefore aims to limit or even prevent the effects of the coupling loss between the radio frequency components and the substrate, and generation of unwanted harmonics.

To this end, the present disclosure provides a semiconductor-on-insulator substrate for radio-frequency applications, comprising:
a silicon carrier substrate,
an electrically insulating layer arranged on the carrier substrate,
a single-crystal layer arranged on the electrically insulating layer,

the substrate being characterized in that it further comprises a layer of silicon carbide SiC arranged between the carrier substrate and the electrically insulating layer, which has a thickness between 1 nm and 5 nm, the surface of the layer of silicon carbide SiC that is on the side of the electrically insulating layer being rough.

The presence of a rough SiC layer allows the drop in resistivity usually observed at the interface between the carrier substrate and the charge-trapping layer to be limited, and a semiconductor-on-insulator substrate that has a better radio-frequency performance to be obtained.

A thickness between 1 nm and 5 nm for the rough SiC layer allows the level of roughness due to the level of roughness of the carrier substrate on which it rests to be reproduced, and thus the surface area of this SiC layer to be maximized.

According to other aspects, the proposed substrate has the various following features, either implemented alone or in technically possible combinations thereof:
the single-crystal layer is a semiconductor layer, i.e., it comprises a semiconductor;
the single-crystal layer is a ferroelectric layer, i.e., it comprises a ferroelectric material. Preferably, the ferroelectric material is chosen from: LiTaO₃, LiNbO₃, LiAlO₃, BaTiO₃, PbZrTiO₃, KNbO₃, BaZrO₃, CaTiO₃, PbTiO₃, KTaO₃.
the surface of the silicon-carbide layer has a roughness higher than or equal to 10 nm RMS, and preferably higher than or equal to 100 nm RMS;
the substrate further comprises a polysilicon charge-trapping layer arranged between the silicon-carbide layer and the electrically insulating layer;
the carrier substrate is single-crystal;
the electrically insulating layer is a silicon-oxide layer.

The present disclosure also relates to a process for fabricating a semiconductor-on-insulator substrate for radio-frequency applications, characterized in that it comprises the following steps:
providing a silicon carrier substrate,
roughening a free surface of the carrier substrate via a selective etch,
forming a silicon-carbide layer on the roughened surface, the surface of the silicon-carbide layer that is on the side opposite the carrier substrate being rough,
forming a bonding layer on the silicon-carbide layer,
transferring an electrically insulating layer and a single-crystal layer to the bonding layer, the electrically insulating layer being at the interface with the bonding layer.

The etch is said to be “selective” in that the silicon from which the carrier substrate is made is not etched uniformly over the entire free surface of the carrier substrate, as certain regions of this surface (corresponding to particular crystal planes) are etched faster than other regions. In this way, the roughening operation is controlled.

The parameterization of the selective etch allows the depth desired for the cavities formed in the thickness of the carrier substrate, from its free surface, to be selected and adjusted, and therefore the roughness expected for the surface of the subsequently formed SiC layer to be adjusted.

According to other aspects, the proposed substrate has the various following features, either implemented alone or in technically possible combinations thereof:
the single-crystal layer is a semiconductor layer, i.e., it comprises a semiconductor;
the single-crystal layer is a ferroelectric layer, i.e., it comprises a ferroelectric material. Preferably, the ferroelectric material is chosen from: LiTaO₃, LiNbO₃, LiAlO₃, BaTiO₃, PbZrTiO₃, KNbO₃, BaZrO₃, CaTiO₃, PbTiO₃, KTaO₃.
the roughening step comprises a selective etch along crystal planes of the free surface of the carrier substrate;
the roughening step comprises:
nucleating silicon-carbide islands on the free surface of the carrier substrate by exposing the free surface to a precursor gas containing carbon-containing chemical species so as to cause a reaction of the carbon-containing chemical species with the silicon of the carrier substrate,
carrying out a selective etch of regions of the free surface of the carrier substrate separating the islands.
the selective etch is a dry etch;
the selective dry etch is carried out with hydrochloric acid;
the silicon-carbide layer is formed by exposing the roughened surface to a precursor gas containing carbon-containing chemical species so as to cause a reaction of the carbon-containing chemical species with the silicon of the carrier substrate;
the silicon-carbide layer on the roughened surface of the carrier substrate is formed by chemical vapor deposition;
the process further comprises, before the electrically insulating layer and the single-crystal layer are transferred, depositing a polysilicon charge-trapping layer on the silicon-carbide layer;
the transferring step comprises:
providing a donor substrate covered with an electrically insulating layer,
forming a weakened region in the donor substrate, so as to define a single-crystal layer,
bonding the donor substrate to the carrier substrate via the electrically insulating layer and the bonding layer,
detaching the donor substrate along the weakened region, so as to transfer the single-crystal layer to the carrier substrate.

### BRIEF DESCRIPTION OF THE DRAWINGS

Other advantages and features of the present disclosure will become apparent upon reading the following description given by way of illustrative and non-limiting example, with reference to the accompanying figures:

FIG. 1 is a schematic illustrating one embodiment of a semiconductor-on-insulator substrate for radio-frequency applications according to the present disclosure;

FIG. 2A is a schematic of a silicon carrier substrate;

FIG. 2B is a schematic illustrating a step of etching the carrier substrate of FIG. 1, according to a first embodiment;

FIG. 2C is a schematic illustrating a step of forming an SiC layer on the etched surface of the substrate of FIG. 2B, according to the first embodiment, to fabricate an intermediate substrate;

FIG. 3A is a schematic illustrating a step of nucleating silicon-carbide islands on a carrier substrate, according to a second embodiment;

FIG. 3B is a schematic illustrating a step of etching the substrate of FIG. 3A;

FIG. 3C is a schematic illustrating growth of the SiC layer until a continuous SiC layer is obtained;

FIG. 4 is a schematic of a semiconductor-on-insulator substrate for radio-frequency applications fabricated from the intermediate substrate obtained via the first embodiment of the process illustrated in the FIGS. 2A, 2B, and 2C;

FIG. 5 is a schematic of a semiconductor-on-insulator substrate for radio-frequency applications fabricated from the intermediate substrate obtained via the second embodiment of the process illustrated in the FIGS. 3A, 3B, and 3C;

FIG. 6 is a graph showing the resistivity as a function of the thickness of the substrate in the case of a semiconductor-on-insulator substrate comprising a smooth layer of silicon carbide SiC or a rough layer of silicon carbide SiC.

### DETAILED DESCRIPTION

A first subject of the present disclosure relates to a semiconductor-on-insulator substrate, which is referred to as the “SOI substrate,” for radio-frequency applications.

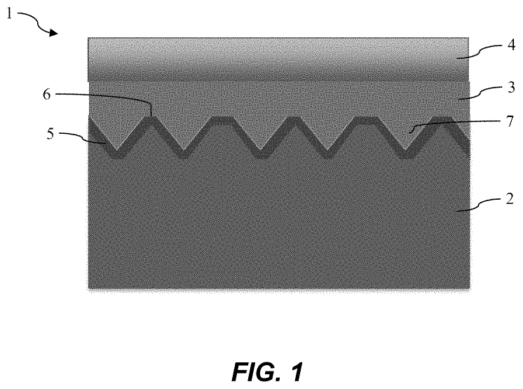

FIG. 1 illustrates an embodiment of the SOI substrate according to the present disclosure.

The SOI substrate, under the reference 1, comprises a silicon carrier substrate 2, an electrically insulating layer 3 arranged on the carrier substrate, and a single-crystal layer 4 arranged on the electrically insulating layer. By “on” what is meant, considering the substrate as a whole, is a relative position of the layers from its bottom (on the side of the carrier substrate) to its surface (on the side of the single-crystal layer), but this term does not necessarily imply direct contact between the layers in question.

The carrier substrate 2 is preferably single-crystal.

The electrically insulating layer 3 is preferably an oxide layer. Due to its positioning in the SOI substrate between the carrier substrate 2 and the single-crystal layer 4, such an oxide layer is generally designated by the term “BOX” for buried oxide. The electrically insulating layer is preferably a silicon-oxide layer.

The single-crystal layer 4 is advantageously an active layer, i.e. a layer intended for the production of radio-frequency components depending on the radio-frequency application desired for the SOI substrate.

The single-crystal layer is preferably a semiconductor layer. Particularly preferably, it is a layer of single-crystal silicon.

According to the present disclosure, the SOI substrate 1 further comprises a layer 5 of silicon carbide (SiC), arranged between the carrier substrate 2 and the electrically insulating layer 3. The SiC layer 5 makes direct contact with carrier substrate 2. In the embodiment of FIG. 1, the SiC layer 5 also makes direct contact with the electrically insulating layer 3.

The silicon carbide is preferably polycrystalline.

The upper surface 6 of the SiC layer, which is located at the interface with the electrically insulating layer, is rough. This means that the upper surface of the SiC layer contains cavities 7. These cavities have a size, i.e., a height (depending on the thickness of the layer) and a width (in a direction perpendicular to the height), that depends on the roughness value of the surface of the SiC layer.

In the semiconductor field, the surface of a substrate is considered to be rough when it does not allow a high-quality bond (i.e., one that has, with regard to subsequent processing steps, a sufficiently high and uniform bonding energy at the contact interface) with another substrate, another semiconductor substrate, for example, which may optionally be covered with an oxide layer.

Generally, a surface is thus said to be rough when it has an RMS roughness of at least 6 angstroms, i.e., 0.6 nanometers (nm).

According to the present disclosure, the surface of the SiC layer preferably has a roughness higher than or equal to 10 nm RMS, and more preferably higher than or equal to 100 nm RMS. RMS roughness corresponds to the root-mean-square of all the ordinates of the roughness profile with the base length in question. Those skilled in the art know to what RMS roughness corresponds and how to measure it. Thus, these elements are not described in detail in the present text.

In FIG. 1, the surface 6 of the SiC layer has been schematically shown as having a sawtooth profile.

The surface of the electrically insulating layer 3 that is located in contact with the SiC layer 5 has a profile complementary to that of the surface of the SiC layer, as illustrated in FIG. 1. More precisely, the lower surface of the electrically insulating layer making contact with the SiC layer has a sawtooth profile the shape of the teeth of which corresponds to the shape of the cavities of the SiC layer.

Consequently, the SiC layer 5, which forms the interface between the carrier substrate 2 and the electrically insulating layer 3, is not smooth but, on the contrary, is irregular, uneven and contains cavities.

The irregular and uneven profile of the SiC layer allows the surface area of the upper surface of the SiC layer, i.e., the surface area of the interface between the SiC layer and the electrically insulating layer, to be increased.

The function of the SiC layer 5 is to trap electric charge carriers present in the SOI substrate. Specifically, the grain boundaries of the SiC layer forming the silicon-carbide crystal trap charge carriers.

Increasing the surface area of the interface between the carrier substrate and the electrically insulating layer therefore allows the trapping of charge carriers in the SOI substrate to be improved, compared with a prior-art polysilicon charge-trapping layer (in particular, because of the absence of recrystallization during subsequent heat treatments), or with a smooth silicon-carbide layer (because of the larger surface area of the interface).

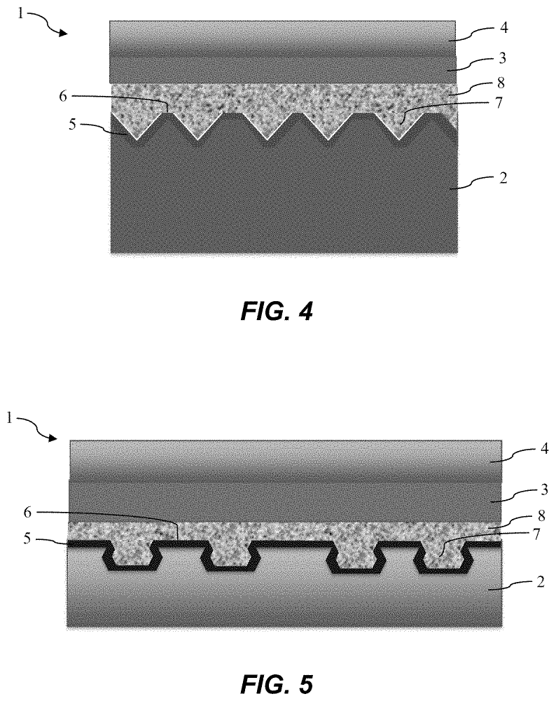

According to a second embodiment illustrated in FIG. 4, the SOI substrate 1 also comprises at least one charge-trapping layer 8 that is different from the SiC layer. Such a charge-trapping layer, which is known per se, is advantageously made of polysilicon.

The charge-trapping layer 8 is arranged between the SiC layer 5 and the electrically insulating layer 3. The combination of the charge-trapping layer and the SiC layer further improves the trapping of charge carriers present within the SOI substrate. In particular, the SiC layer limits recrystallization of the polysilicon of the charge-trapping layer. Specifically, the SiC layer forms a barrier between the silicon of the carrier substrate 2 and the polysilicon grains of the charge-trapping layer 8, thus preventing the polysilicon grains from recrystallizing according to the carrier substrate.

A process for fabricating an SOI substrate such as presented above will now be described.

The process of the present disclosure first of all involves, starting with the silicon carrier substrate, roughening a free surface of the carrier substrate via a selective etch. This allows cavities to be formed in the free surface of the carrier substrate. A layer of silicon carbide SiC is then formed on the roughened surface.

The type of selective etch and the etch parameters are chosen and adjusted depending on the desired depth of the cavities, and therefore on the roughness expected for the surface of the subsequently formed SiC layer.

The roughening operation may advantageously be carried out according to two different embodiments that will now be described.

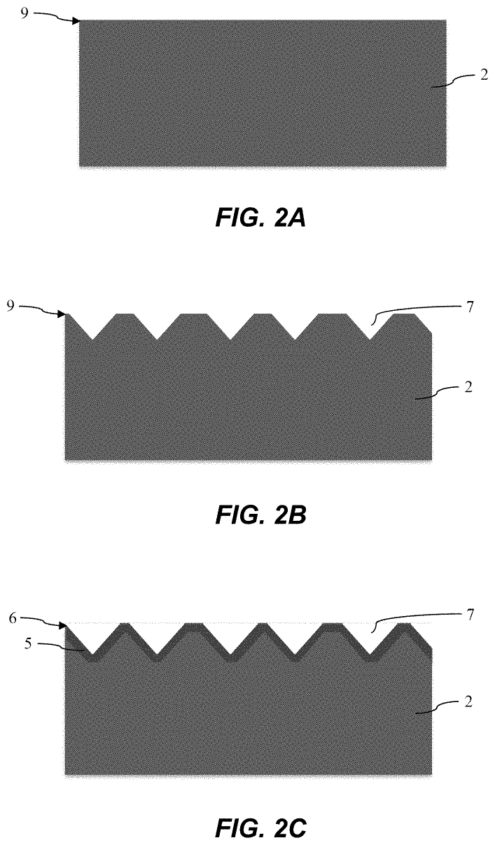

According to a first embodiment of the roughening operation, with reference to FIGS. 2A, 2B, and 2C, a carrier substrate 2 (shown in FIG. 2A) is first provided.

A free surface 9 of the carrier substrate is roughened via a selective etch. The substrate of FIG. 2B is then obtained.

The etch is said to be “selective” in that the silicon is not etched uniformly over the entire surface of the substrate, as certain regions of the surface (corresponding to particular crystal planes) are etched faster than other regions.

The selective etch is preferably a dry etch. Hydrochloric acid is particularly suitable for this etch.

An SiC layer 5 is then formed on the etched surface, as illustrated in FIG. 2C.

To do this, according to a first embodiment, the etched surface 9 is exposed to a precursor gas containing carbon-containing chemical species. The latter react with the silicon present in the carrier substrate, to form silicon carbide SiC. The SiC layer therefore grows from the roughened surface, in the thickness of the carrier substrate. As a result, the free surface of the surface of the SiC layer (which was initially the surface of the silicon carrier substrate) remains rough.

The experimental parameters of the formation of the SiC layer, such as exposure time, reaction temperature, or the nature of the precursor gas, are adjusted so as to form a thin SiC layer, and preferably one of thickness smaller than or equal to 5 nm. It is also preferable for the thickness of the SiC layer to be larger than or equal to 1 nm. Given the temperature applied, the SiC layer advantageously has a polycrystalline structure.

The etch is preferably carried out at a temperature between 700° C. and 1300° C., at atmospheric pressure or at a pressure below atmospheric pressure. Hydrochloric acid HCl in gaseous form is preferably used for the etch.

As regards the formation of the SiC layer, it is preferably carried out at a temperature between 700° C. and 1300° C., and at a pressure below atmospheric pressure. It is especially possible to use, as precursor gas, propane or methane in hydrogen. The reaction time depends on the amount of precursor gas; specifically, the reaction is self-limiting, i.e., the carbon-containing gas reacts with the silicon on the surface of the carrier substrate and the reaction stops when there is no longer any silicon on the free surface.

Alternatively, according to a second embodiment, the SiC layer is deposited on the etched surface by chemical vapor deposition (CVD). The SiC layer grows from the roughened surface, away from the carrier substrate. This embodiment is less preferred because, since the SiC layer is deposited at a lower temperature than in the previous embodiment, it has an amorphous structure. The SiC layer is deposited substantially uniformly over the whole of the etched surface, but this deposition does not fill the cavities of the etched surface, and hence the free surface of the SiC layer at least partially retains the roughness of the subjacent surface 9.

Optionally, a polysilicon charge-trapping layer 8 is deposited on the SiC layer.

Particularly advantageously, the steps of carrying out a selective etch, of forming the SiC layer and optionally the charge-trapping layer are carried out in the same epitaxy reactor, this considerably simplifying the process. Alternatively, the steps may be carried out by means of at least two different pieces of equipment.

No smoothing or planarizing operation is carried out on the formed SiC layer. Chemical-mechanical polishing (CMP), for example, would moreover be impossible to carry out because of the small thickness of the SiC layer.

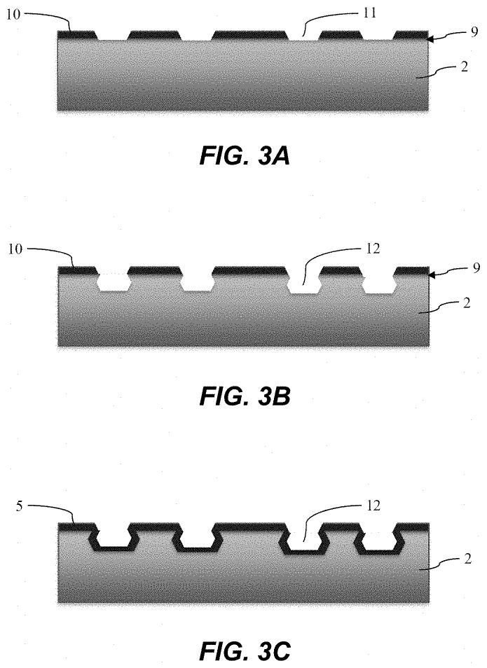

According to a second embodiment of the roughening operation, with reference to FIGS. 3A, 3B, and 3C, a carrier substrate (shown in FIG. 3A) is first provided.

The free surface 9 of the carrier substrate is then roughened, in two steps. A first step comprises nucleating (or germinating) silicon-carbide islands 10 on the upper surface. To do this, the upper face 9 is first exposed to a precursor gas containing carbon-containing chemical species. The latter react with the silicon present in the carrier substrate, to form silicon carbide SiC.

Silicon-carbide islands 10 are obtained by stopping exposure to carbon-containing chemical species before the islands coalesce and form a continuous SiC layer on the etched surface. At the end of this nucleating step, the SiC islands are separated from one another by silicon regions 11.

In a second step of the roughening process, a selective etch is carried out on the carrier substrate. The etch is said to be “selective” in that only the silicon regions are etched, whereas the SiC islands 10 are not. Specifically, the SiC islands play the role of a mask that protects the material of the subjacent carrier substrate from the etch. The selective etch is preferably a dry etch. Hydrochloric acid is particularly suitable for this etch.

After the etch, the substrate of FIG. 3B is obtained.

Each island 10 comprises a segment of the carrier substrate covered with a SiC layer, and is separated from adjacent islands by the etched silicon regions 12, the islands and the etched regions together forming a rough surface of the carrier substrate.

The formation of the SiC layer (growth) is then continued until a continuous SiC layer 5 is obtained, as illustrated in FIG. 3C.

To do this, according to a first embodiment, the roughened surface 9 is exposed to a precursor gas containing carbon-containing chemical species. The latter react with the silicon present in the carrier substrate, to form silicon carbide SiC.

The experimental parameters of the formation of the SiC layer, such as exposure time, pressure, reaction temperature, or the nature of the precursor gas, and the flow rate of the precursor gas are adjusted so as to form a thin SiC layer, and preferably one of thickness smaller than or equal to 5 nm. It is also preferable for the thickness of the SiC layer to be larger than or equal to 1 nm.

The SiC layer is preferably formed at a temperature between 700° C. and 1300° C., at a pressure below atmospheric pressure. The reaction time is preferably about a few minutes for temperatures comprised in the above range of 700° C. to 1300° C. The flow-rate ratio between the carbon-containing gas and hydrogen influences germination and growth rates and the final thickness of the SiC layer.

Alternatively, the SiC layer may be deposited on the roughened surface by CVD as described above with respect to the first embodiment of the roughening operation.

Optionally, a polysilicon charge-trapping layer 8 is deposited on the SiC layer.

Particularly advantageously, the steps of nucleating the SiC islands, of carrying out a selective etch, of continuing the formation of the SiC layer and optionally of forming the charge-trapping layer are carried out in the same epitaxy reactor, this considerably simplifying the process.

Whatever the embodiment, after the free surface 9 of the carrier substrate has been roughened, a bonding layer is formed on the SiC layer, then an electrically insulating layer 3 and a single-crystal layer 4 are transferred to the bonding layer, so that the electrically insulating layer is located at the interface with the bonding layer. Unlike the SiC layer, the bonding layer has a smooth surface suitable for ensuring a high-quality bond.

The bonding layer ensures a good adhesion of the electrically insulating layer 3 and single-crystal layer 4 to the SiC layer 5. It may be a layer of silicon oxide, an adhesive layer, an adhesive, or any other means suitable for this purpose.

According to one preferred embodiment, the transfer is carried out using the well-known SMARTCUT™ process, the main stages of which are recalled below.

A first substrate, called the receiver substrate, which comprises the carrier substrate 2, the layer 5 of silicon carbide SiC, and the bonding layer, is provided. Optionally, the receiving substrate comprises a charge-trapping layer 8 on the SiC layer, and the bonding layer is arranged on the charge-trapping layer. A second substrate, called the donor substrate, is also provided.

A weakening region is formed in the donor substrate, so as to define a single-crystal layer 4. The weakened region is formed in the donor substrate at a predefined depth that substantially corresponds to the thickness of the single-crystal layer to be transferred.

Preferably, the weakened region is created by implanting atoms and/or ions of hydrogen and/or of helium in the donor substrate.

The donor substrate is then bonded to the receiver substrate.

An electrically insulating layer 3 is arranged between the carrier substrate 2 and the single-crystal layer 4.

According to a first embodiment, the electrically insulating layer 3 is on the receiver substrate, the layer being arranged on the SiC layer 5 or, when it is present, on the charge-trapping layer 8. The single-crystal layer 4 is bonded to the electrically insulating layer 3 and is therefore located at the bonding interface.

According to a second embodiment, the electrically insulating layer 3 is on the donor substrate. Both the single-crystal layer 4 and the electrically insulating layer 3 are bonded to the SiC layer by means of the bonding layer. The electrically insulating layer 3 is therefore located at the bonding interface.

The layer-transferring process is not however limited to the SMARTCUT™ process; thus, it will possibly consist, for example, in bonding the donor substrate to the receiver substrate and then in thinning the donor substrate via its face opposite the receiver substrate until the desired thickness is obtained for the single-crystal layer.

The SOI substrates 1 obtained after transfer according to the first embodiment and the second embodiment are shown in FIGS. 4 and 5, respectively.

According to one embodiment, the single-crystal layer 4 comprises a ferroelectric material.

The ferroelectric material is advantageously chosen from: LiTaO₃, LiNbO₃, LiAlO₃, BaTiO₃, PbZrTiO₃, KNbO₃, BaZrO₃, CaTiO₃, PbTiO₃ and KTaO₃.

The donor substrate of the single-crystal layer may advantageously take the form of a circular wafer of standardized size, for example, of 150 mm or 200 mm diameter. The present disclosure is not however in any way limited to these dimensions or to this form. The wafer may have been obtained from an ingot of ferroelectric material, in such a way as to form a donor substrate having a preset crystal orientation. Alternatively, the donor substrate may comprise a layer of ferroelectric material joined to a carrier substrate.

The crystal orientation of the single-crystal layer of ferroelectric material to be transferred is chosen depending on the intended application. Thus, as regards the material LiTaO₃, it is conventional to choose an orientation between 30° and 60° XY, or between 40° and 50° XY, in particular, in the case where it is desired to exploit the properties of the thin layer to form a SAW filter (SAW being the acronym of Surface Acoustic Wave). As regards the material LiNbO₃, it is conventional to choose an orientation of about 128° XY. However, the present disclosure is not in any way limited to a particular crystal orientation.

Whatever the crystal orientation of the ferroelectric material of the single-crystal layer 4, the process, for example, comprises introducing species (ions and/or atoms) of hydrogen and/or helium into the donor substrate. This introduction may, for example, correspond to a hydrogen implantation, i.e., a hydrogen ion bombardment of the planar face of the donor substrate.

As known per se, the purpose of the implanted atoms or ions is to form a weakened plane defining a first layer of ferroelectric material to be transferred and another portion forming the rest of the substrate. The nature, the dose of the implanted species and the type of implanted species, and the implantation energy, are chosen depending on the thickness of the layer to be transferred and on the physicochemical properties of the donor substrate. In the case of a donor substrate made of LiTaO₃, it will thus more particularly possibly be chosen to implant a dose of hydrogen between 1E16 and 5E17 at/cm² with an energy between 30 and 300 keV in order to define a first layer of about 20 to 2000 nm thickness.

### Example: Measurement of Electrical Resistivity

Two substrates were initially provided.

A first substrate was fabricated by depositing a SiC layer on a carrier substrate the free surface of which was smooth, i.e., without carrying out an etch beforehand, then transferring an electrically insulating layer and a single-crystal layer to the SiC layer. The upper surface of the SiC layer, on the side of the electrically insulating layer, was therefore smooth.

A second substrate was fabricated according to one of the two embodiments of the fabricating process that were described above. This second substrate therefore comprised a carrier substrate, a SiC layer the upper surface of which was rough, and an electrically insulating layer and a single-crystal layer arranged on the rough SiC layer.

The electrical resistivity of each of the two substrates was measured, for example, by four-point probe.

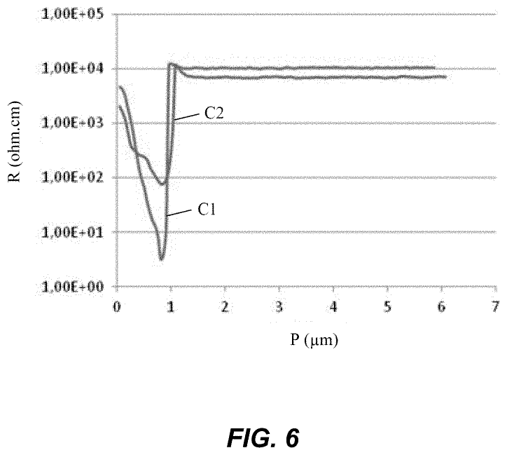

FIG. 6 represents the variation in the electrical resistivity R (in ohm·cm) of the substrates as a function of their depth P (in μm) from the surface of the single-crystal layer for the first substrate, the SiC layer of which was smooth (curve C1), and for the second substrate, the SiC layer of which was rough (curve C2).

Regarding curve C1, the resistivity drops sharply from the free surface of the substrate to a depth slightly smaller than 1 μm, which corresponds to the depth of the SiC layer, reaching a minimum value of about 5 Sam.

Regarding curve C2, the resistivity drops much less than for curve 1, from the free surface of the substrate to a depth slightly less than 1 μm, reaching a minimum value of about 90 Sam.

These curves show that the rough SiC layer allows the effect of the interface between the carrier substrate and the trapping layer to be limited. The larger the drop in resistivity at the interface, the more this drop has a negative impact on the overall trapping performance of the SiC layer.

1. A semiconductor-on-insulator substrate for radio-frequency applications, comprising:
a silicon carrier substrate;
an electrically insulating layer arranged on the carrier substrate;
a single-crystal layer arranged on the electrically insulating layer; and
a layer of silicon carbide SiC arranged between the carrier substrate and the electrically insulating layer, the layer of silicon carbide having a thickness between 1 nm and 5 nm, a surface of the layer of silicon carbide on the side of the electrically insulating layer being rough.

2. The substrate of claim 1, wherein the single-crystal layer is a semiconductor layer.

3. The substrate of claim 1, wherein the single-crystal layer comprises a ferroelectric material.

4. The substrate of claim 3, wherein the ferroelectric material comprises at least one material chosen from among: LiTaO3, LiNbO3, LiAlO3, BaTiO3, PbZrTiO3, KNbO3, BaZrO3, CaTiO3, PbTiO3, and KTaO3.

5. The substrate of claim 1, wherein the surface of the silicon-carbide layer has a roughness higher than or equal to 10 nm RMS.

6. The substrate of claim 1, further comprising a polysilicon charge-trapping layer arranged between the silicon-carbide layer and the electrically insulating layer.

7. The substrate of claim 1, wherein the carrier substrate is a single-crystal carrier substrate.

8. The substrate of claim 1, wherein the electrically insulating layer comprises a silicon-oxide layer.

9. A method of fabricating a semiconductor-on-insulator substrate for radio-frequency applications, comprising the following steps:
providing a silicon carrier substrate;
roughening a free surface of the carrier substrate via a selective etch;
forming a silicon-carbide layer on the roughened surface, the surface of the silicon-carbide layer on the side opposite the carrier substrate being rough;
forming a bonding layer on the rough surface of the silicon-carbide layer; and
transferring an electrically insulating layer and a single-crystal layer to the bonding layer, the electrically insulating layer being at an interface with the bonding layer.

10. The method of claim 9, wherein the single-crystal layer is a semiconductor layer.

11. The method of claim 9, wherein the single-crystal layer comprises a ferroelectric material.

12. The method of claim 11, wherein the ferroelectric material comprises at least one material chosen from among: LiTaO3, LiNbO3, LiAlO3, BaTiO3, PbZrTiO3, KNbO3, BaZrO3, CaTiO3, PbTiO3, and KTaO3.

13. The method of claim 9, wherein the roughening step comprises a selective etch along crystal planes of the free surface of the carrier substrate.

14. The method of claim 9, wherein the roughening step comprises:
nucleating silicon-carbide islands on the free surface of the carrier substrate by exposing the free surface to a precursor gas containing carbon-containing chemical species to cause a reaction of the carbon-containing chemical species with the silicon of the carrier substrate; and
carrying out a selective etch of regions of the free surface of the carrier substrate separating the islands.

15. The method of claim 13, wherein the selective etch is a dry etch.

16. The method of claim 15, wherein the selective dry etch is carried out with hydrochloric acid.

17. The method of claim 9, further comprising forming the silicon-carbide layer by exposing the roughened surface to a precursor gas containing carbon-containing chemical species to cause a reaction of the carbon-containing chemical species with the silicon of the carrier substrate.

18. The method of claim 9, further comprising forming the silicon-carbide layer on the roughened surface of the carrier substrate by chemical vapor deposition.

19. The method of claim 9, further comprising, depositing a polysilicon charge-trapping layer on the silicon-carbide layer before the step of transferring the electrically insulating layer and the single-crystal layer.

20. The method of claim 9, wherein the transferring step comprises:
providing a donor substrate covered with an electrically insulating layer;
forming a weakened region in the donor substrate to define a single-crystal layer;
bonding the donor substrate to the carrier substrate via the electrically insulating layer and the bonding layer; and
detaching the donor substrate along the weakened region, so as to transfer the single-crystal layer to the carrier substrate.
